(19) United States
(12) Patent Application Publication
(10) Pub. No.: US 2014/0354312 A1
(43) Pub. Date: Dec. 4, 2014

(54) TEST HANDLER, TEST CARRIER AND TEST METHOD THEREOF

(71) Applicants: Kai-Ming Li, Zhubei City (TW); Chih-Lung Chien, Zhubei City (TW)

(72) Inventors: Kai-Ming Li, Zhubei City (TW); Chih-Lung Chien, Zhubei City (TW)

(73) Assignee: RICHTEK TECHNOLOGY CORPORATION, Zhubei City (TW)

(21) Appl. No.: 14/277,185

(22) Filed: May 14, 2014

(30) Foreign Application Priority Data
May 28, 2013 (TW) 102118724

(51) Int. Cl. G01R 31/28

(52) U.S. Cl. CPC G01R 31/2891
USPC 324/750.03

(57) ABSTRACT

The present invention provides a test handler for various IC tests, which includes a chamber and a test carrier. The chamber is controllable to present a dry status. The test carrier is made of a high thermal-conductive material and includes plural positioning structures for respectively accommodating plural IC chips. The test carrier is disposed on and in thermal contact with a temperature-adjustment device in the chamber, and the temperature-adjustment device controls the temperature of the IC chips on the test carrier by thermal conduction through the test carrier. The invention also provides a test carrier used in the test handler and a test method thereof.

### CROSS REFERENCE

The present invention claims priority to TW 102118724, filed on May 28, 2013.

### BACKGROUND OF THE INVENTION

1. Field of Invention

The present invention relates to a test handler, especially a test handler including plural positioning structures to accommodate IC chips, wherein a temperature of the IC chips is controlled by thermal conduction.

2. Description of Related Art

A test handler for IC chips performs tests such as temperature tests according to customers' requests or practical needs. The throughput of a test is usually limited by the processing capability of the test handler. FIG. 1 shows a prior art turret handler 10, which is one kind of the test handler, wherein IC chips enter the turret handler 10 at the entrance site I and afterwards follow a rotation of a rotating plate to enter different sites for various tests. As an example, four sites T1, T2, T3, and T4 are provided for different function tests (or same function test); after the tests, qualified IC chips passing through the tests can be packed at the site Pas, and disqualified IC chips can be collected at the site Fai. Such turret handler usually includes 2 to 4 test sites; if more sites are added, the processing capability of the test handler can be increased but the related size and cost of the test handler will multiply. Besides, the site number of such test handler is limited and the maximum site number can only be up to 16. The environment temperature tests usually include room temperature, high temperature, and low temperature tests; however, the temperature test that the turret handler 10 can perform is limited by its structure; in fact, it can only perform the room temperature test. For a low temperature test below 0° C., the chamber of the tester must be sealed to avoid frost or ice caused by external moisture, and even if the temperature is not below 0° C., there could be dew generated at or below 5° C.-6° C. because of the moisture. Therefore, it is very difficult to realize such low temperature test in the turret handler. Another limitation of the turret handler is the size of the IC chips; because the IC chips are picked and placed by vacuum suckers, the size of tested IC chips can not be smaller than the minimum size that can be handled by the vacuum suckers. In short, the turret handler has the disadvantages of low throughput (limited number of chips per test), expensive facility cost, incapability of non-room temperature test, and limited size of IC chips under test.

FIG. 2 shows a prior art pick & place handler 20, which is another kind of test handler. It operates as thus: first, the IC chips under test are placed in a tray and transmitted into a preheating area in an enclosed chamber 21 to preheat or pre-cool the IC chips by a working gas provided in the preheating area. Next, the IC chips are picked up from the preheating area and placed into a testing area for test; after finishing the test, the IC chips are picked up from the testing area and placed back in the tray. The operation requires numerous pick-and-place actions which are usually done by vacuum suckers, so the size of the IC chips can not be smaller than the minimum size that can be handled by the vacuum suckers. Although the pick & place handler 20 is capable of performing room temperature, high temperature, and low temperature tests, it requires a preheating area which occupies a large space. Further, because the pick & place handler 20 uses the working gas to heat or cool the IC chips in the preheating area for non-room temperature tests, the heating or cooling step takes long time; in case any malfunction occurs in a non-room temperature test, the enclosed chamber 21 needs to be recovered to the room temperature for trouble shooting, and then heated or cooled back to the test temperature. The process takes very long time that will greatly reduce the throughput. As shown in FIG. 2, there are four test positions in testing area and correspondingly four vacuum suckers are needed. When more test positions are provided, the corresponding size, components, and cost of the equipment will greatly increase. Due to the restriction of the vacuum suckers each of which requires a space to stand-by and a path to move, the number of the test positions is very limited and 32 test positions are the maximum. In summary, the pick & place handler has the disadvantages of high facility cost, requiring a large space, low throughput (limited number of chips per test), long heating and cooling time for non-room temperature tests, and limited size of IC chips under test.

FIG. 3 shows a prior art gravity handler 30, which is another kind of the test handler. During test, IC chips fall downward by gravity through tracks into testing areas 32. After the IC chips are determined qualified or disqualified, the IC chips are transmitted into pass bins Pasb or fail bins Faib by a shuttle 33. To perform non-room temperature tests, a preheating area 31 is also provided and a working gas is used to preheat or pre-cool the IC chips in the preheating area 31. Despite no vacuum sucker is needed, the gravity handler 30 still has similar disadvantages as the pick & place handler, because the tracks and shuttle 33 occupy a large space; if the number of IC chips per test is to be increased, the size and cost will multiply. Besides, the gravity handler still has its limitation with respect to the weight or size of the IC chips under test; in case the weight of the IC chip is too light, the friction generated by the inner wall of the track may be larger than the weight of the IC chip such that IC chips can not fall along the track smoothly; in case the size of the IC chip is too big, the IC chip may not be able to enter the track. In short, the gravity handler has similar disadvantages as the pick & place handler: high facility cost, requiring a large space, low throughput (limited number of chips per test), long heating and cooling time for non-room temperature tests, and limited size of IC chips under test.

According to the above, the prior art test handlers are not satisfactory, and problems such as low throughput, poor expandability, multiplied cost for upgrading throughput, long heating and cooling time for non-room temperature tests, and limited size of IC chips under test, require to be solved.

### SUMMARY OF THE INVENTION

The present invention proposes a test handler, a test carrier and a test method thereof.

In one perspective of the present invention, a test handler for multiple IC tests is provided, and the IC tests for example include tests in multiple temperature environments. The test handler includes: a chamber; a temperature-adjustment device in the chamber; a test carrier in the chamber, including a plurality of positioning structures for respectively accommodating the IC chips, the test carrier being in thermal contact with the temperature-adjustment device, wherein the temperature-adjustment device controls the temperature of the IC chips on the test carrier by thermal conduction through the test carrier; and a test fixture in the chamber, for testing the IC chips. The test carrier is preferably made of a high thermal-conductive material.

In a preferable embodiment, the temperature-adjustment device is a supporter including a pipe connected to an external heating/cooling fluid source, and the test carrier is disposed on the temperature-adjustment device. The temperature-adjustment device is preferably movable and while moving, the temperature-adjustment device moves the test carrier along with the temperature-adjustment device for aligning the test carrier with respect to the test fixture.

In a preferable embodiment, the IC chips are inserted, pressed, plugged, or sucked into the positioning structures and a side of each IC chip which has contact pins face upwards.

In a preferable embodiment, the test fixture includes at least one probe, and the test handler further includes a cleaning pad in the chamber for cleaning the probe.

In a preferable embodiment, the test handler further comprising an image sensor for sensing the position of the test fixture and/or the test carrier, and the test carrier and the test fixture are aligned with each other according to the information obtained by the image sensor.

In a preferable embodiment, the test carrier is made of a high termal conductive material and has a circular wafer shape.

In a preferable embodiment, the chamber is controllable to present a dry status.

In another perspective of the present invention, a test carrier for use in a chamber of a test handler is provided, wherein the test handler includes a temperature-adjustment device. The test carrier includes a plurality of positioning structures for respectively accommodating IC chips, and the test carrier being made of a high thermal-conductive material, whereby the test carrier controls the temperature of the IC chips by transferring heat from/to the temperature-adjustment device by thermal conduction when the test carrier is placed in contact with the temperature-adjustment device.

In another perspective of the present invention, a test method for IC chips is provided. The test method includes: providing a chamber including a temperature-adjustment device and a test fixture; providing a test carrier including a plurality of positioning structures; respectively accommodating a plurality of IC chips in the positioning structures; disposing the test carrier in thermal contact with the temperature-adjustment device; and testing the IC chips by the test fixture.

In one preferable embodiment, by termal contact between the test carrier and the temperature-adjustment device, temperature of the IC chips is controlled by thermal conduction wherein heat is transferred from/to the temperature-adjustment device.

The objectives, technical details, features, and effects of the present invention will be better understood with regard to the detailed description of the embodiments below, with reference to the drawings.

### BRIEF DESCRIPTION OF THE DRAWINGS

FIG. 1 shows a prior art test handler.

FIG. 2 shows another prior art test handler.

FIGS. 3 shows another prior art test handler.

FIGS. 4 show a preferable embodiment of the test handler according to the present invention.

FIGS. 5 shows preferable embodiment of the test carrier according to the present invention.

FIGS. 6A and 6B illustrate how the test fixture is aligned to the IC chips according to a preferable embodiment of the present invention.

FIGS. 7A and 7B show examples of cleaning the test fixture according to a preferable embodiment of the present invention.

FIG. 8 shows a flowchart of the test method according to a preferable embodiment of the present invention.

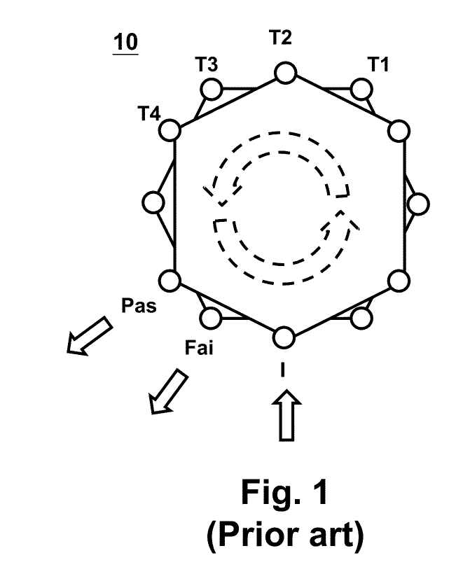

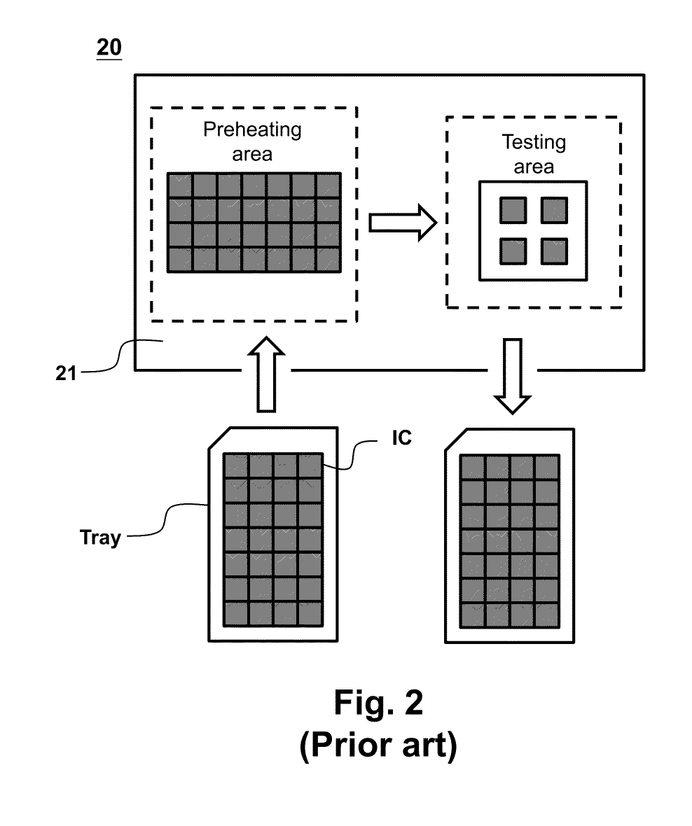

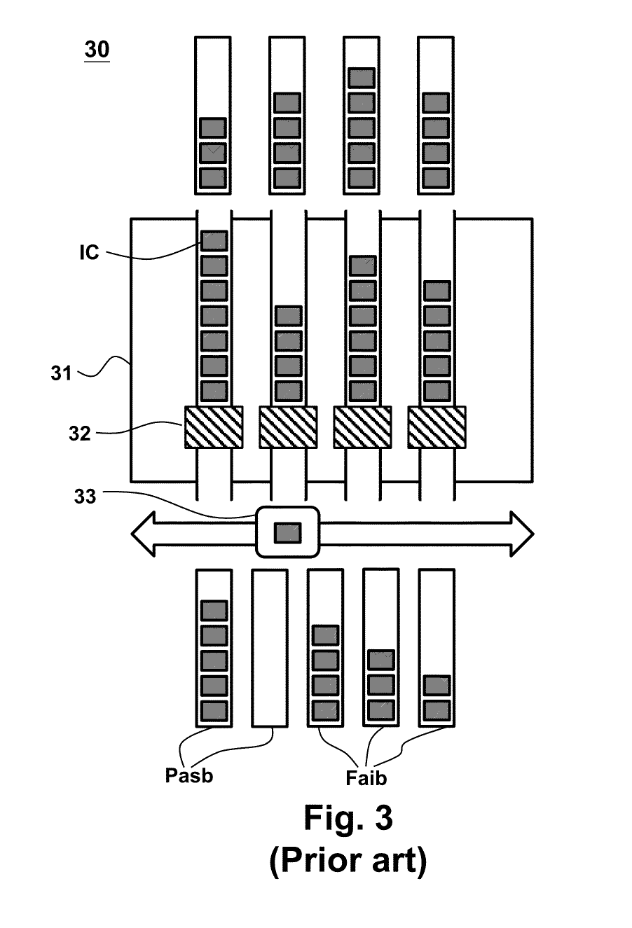

### DESCRIPTION OF THE PREFERRED EMBODIMENTS

The drawings as referred to throughout the description of the present invention are for illustrative purpose only, but not drawn according to actual scale. The orientation wordings in the description such as: above, under, left, or right are for reference with respect to the drawings, but not for limiting the actual product made according to the present invention.

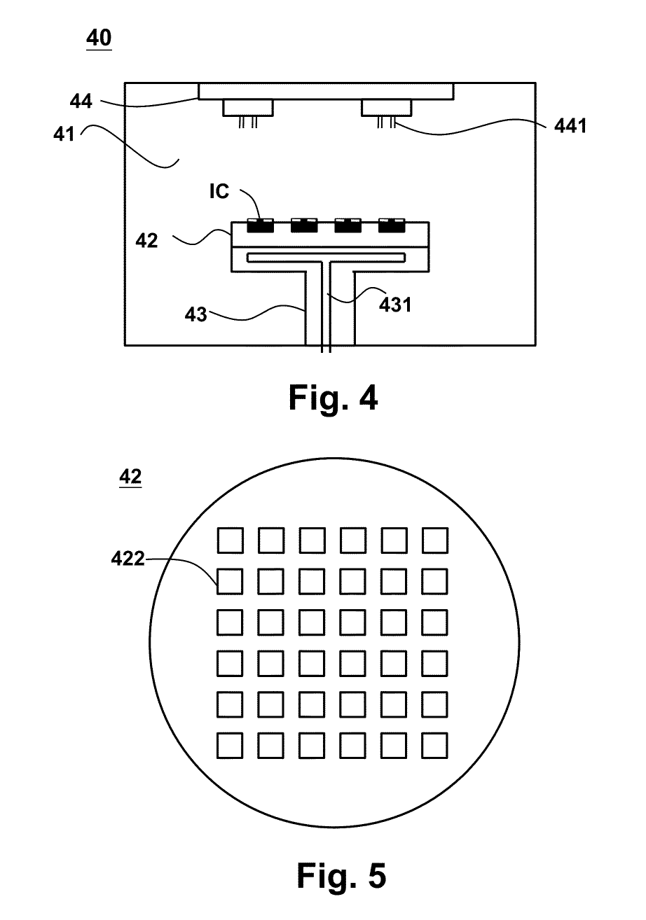

FIG. 4 shows an embodiment of the test handler 40 for multiple IC tests according to the present invention. The test handler 40 includes: a chamber 41, a test carrier 42, a temperature-adjustment device 43, and a test fixture 44. If the test handler 40 is required to perform a non-room temperature test, preferably, the chamber 41 is controllable to present a dry status. The dry status can prevent frost or ice from condensing on the IC chips on the test carrier 42 during low temperature tests below 5° C.-6° C. If the air moisture is too high to cause dew or frost on the IC chips under test, the test may not be able to obtain accurate characteristics of the IC chips. The dry status can be achieved by compressed air, liquid nitrogen, or other methods to provide dry air. The chamber 41 can be sealed, or semi-sealed with an air wall to block external air. The environment moisture requirement for high temperature test is less stringent. If the test handler 40 is used for room temperature test only, the requirements of sealing and moisture control can be lower.

The test carrier 42 can be made of a high thermal-conductivity material such as a metallic material or a material having a thermal-conductivity similar to metal. The test carrier 42 for example can have, but is not limited to, a circular wafer shape similar to a semiconductor wafer (FIG. 5), but it certainly can be any other shape. The test carrier 42 includes plural positioning structures (422, FIG. 5) for accommodating IC chips under test. The number of the positioning structures depends on the sizes of the test carrier 42 and the IC chips under test, and the number can be hundreds or over a thousand if necessary. The test carrier is disposed on and in thermal contact to the temperature-adjustment device 43, wherein the temperature-adjustment device 43 controls the temperature of the IC chips on the test carrier 42 by thermal conduction transferred through the test carrier 42 to the IC chips. According to FIGS. 4 and 5, the positioning structures 422 for example can be, but are not limited to having a recess structure of a rectangular shape; the positioning structures 422 can be other structures of other shapes, and the structure and the shape can be designed according to the requirements of test, placing, picking, and thermal conduction performance. For example, the middle part of two or four sides of the rectangular shape can be widened so that an IC chip is more easily picked up. In one embodiment, the IC chips can be pressed into the plural positioning structures 422 by an elastic tool, to fix the IC chips into proper positions with thermal contact to the test carrier 42. The IC chips can be put into the positioning structure 422 by any other way not limited to the above, such as by inserting, plugging, or sucking into the positioning structures 422. In one embodiment, the IC chips are put into the positioning structure 422 off-line (i.e., not during when the test handler 40 is processing a test), such that the throughput of the test handler 40 is not influenced.

The temperature-adjustment device 43 shown in FIG. 4 can be a supporter in the test handler 40; this supporter can support the test carrier 42 and move the test carrier 42 if it is necessary to align the test carrier 42 to the test fixture 44 (the supporter can include or can be connected to a motion device, not shown in the figure). The supporter includes a pipe 431 connected to an external heating/cooling fluid source whereby the heating/cooling fluid can flow inside the pipe 431 to control temperature. Of course, the temperature-adjustment device 43 can include only temperature adjusting function but no sustaining function; for example, the test carrier 42 may be supported by other structure.

In this embodiment of the present invention, it is not required to provide a separate chamber to preheat/pre-cool the IC chips for non-room temperature test as the prior art test handlers require, and multiple temperature tests can be done on the same IC chips in the same chamber; thus, the present invention avoids the trouble and the possible malfunction that is caused by repeatedly picking and placing IC chips; the throughput can therefore be improved. Besides, because the heat transfer efficiency of thermal conduction is higher than convection by air, the temperature adjustment of this embodiment is faster than the prior art test handlers. Further, the number of the IC chips that can be tested per test (i.e., in one round of temperature-adjustment) is determined by the number of the positioning structures but is not limited by the size of the test handler, the number of the vacuum suckers, or the number of the tracks; therefore, the number of IC cips that can be tested per test is almost unlimited and the throughput can be extremely high. For example, hundreds of IC chips can be accommodated in the test carrier 42 and tested within one round of temperature-adjustment, which is much higher than any prior art. If the IC chip size is different, the present invention only has to replace a different test carriers 42, and it is not necessary to materially change the mechanical structure and components of the test handler such as the rotation plate, the track or the like; the present invention has better expandability than the prior art test handlers. According to the above, the test handler 40 of the present invention has lower facility cost, simpler structure, and better operation efficiency as compared with the prior art test handlers. Furthermore, the sizes and shapes of the chamber 41, the test carrier 42 and the temperature-adjustment device 43 can be designed to match existing semiconductor equipments such that some common parts can be shared, and the housing of the chamber 41 can use the housing of an obsolete (retired) semiconductor equipment for cost saving.

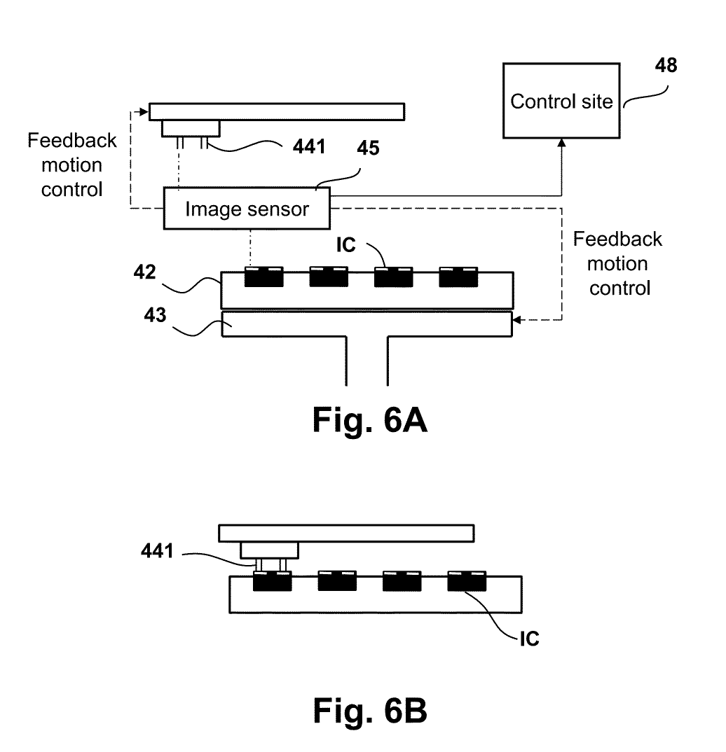

The test handler 40 includes a test fixture 44; this test fixture 44 includes probes to perform various tests on the IC chips. The test fixture 44 can include or can be connected a motion device (not shown) so that it can be moved for alignment to the test carrier 42 if necessary. As an IC chip is placed on the test carrier 42, the side having the contact pins preferably faces upwards such that the probes 441 of the test fixture 44 can probe the IC chips easily. The test of the IC chips can be performed sequentially or in parallel; i.e., the IC chips can be tested one after another, or multiple IC chips can be tested at the same time. Conventionally, the alignment of the test fixture with respect to an IC chip under test is calibrated according to a reference point. The drawback of such conventional arrangement is the difficulty to maintain accuracy when the number of IC chips to be tested is large and the respective positions of the IC chips deviate from expected, which may be due to deviation of size of the IC chips or that the structure of the test handler is worn of by long-term use. In one embodiment of the present invention, the alignment is achieved by image identification, whereby the test fixture and the IC chip under test can be aligned with each other by real-time fine-tuned adjustment of the relative positions, so it is more accurate and it is less likely to require manual trouble shooting. FIGS. 6A and 6B show an example of the image identification. Referring to FIG. 6A, an image sensor 45 senses images which include the positions of the test fixture 44 (probes 441) and/or the test carrier 42 (contact pins of the IC chips), and a relative distance therebetween is obtained; based on the distance information, the position of the test fixture 44 or the test carrier 42 (or the supporter supporting the test carrier 42, such as the temperature-adjustment device 43) is adjusted so that the probes can touch the pins of the IC chips at accurate positions to do the test. In one embodiment, the distance information obtained by the image sensor 45 is used to feedback control the relative movement of the test fixture 44 with respect to the test carrier 42, as shown in FIG. 6A. In another embodiment, the image sensor 45 can transmit the position and distance information to a control site 48 (which can be located outside the chamber 41) and display the distance for manual monitor and control.

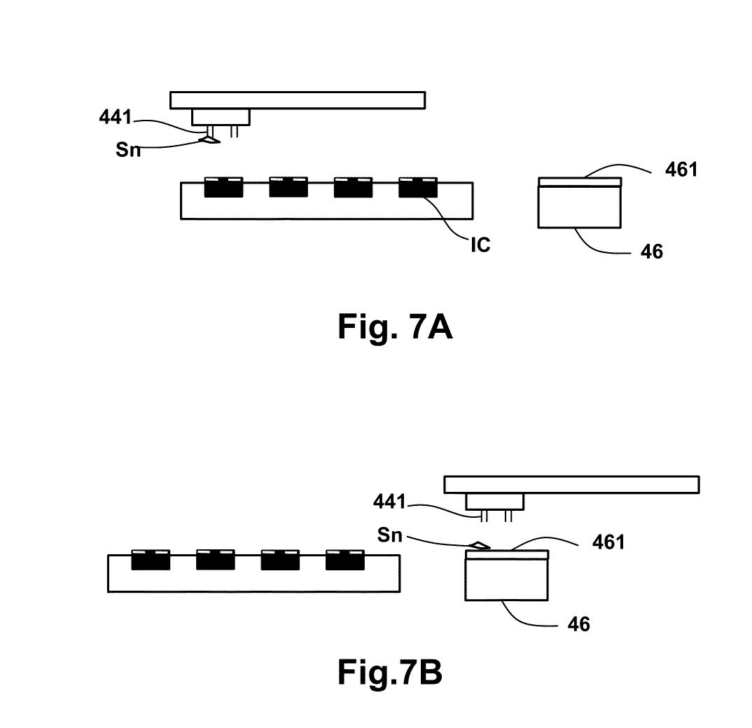

As the probes 441 are used for a long time, dirt can stick on them (such as the dirt Sn shown in FIG. 7A). Therefore, a cleaning pad 46 can be provided in the chamber as shown in FIGS. 7A and 7B, which may be used to clean the probes 441. The cleaning pad 46 can move upward, downward, leftward and/or rightward to clean the dirt on the probes 441. If preferable, the cleaning pad 46 can include an emery paper 461 to enhance the cleaning effect. The cleaning pad 46 can be disposed at a suitable location (such as a corner) in the chamber 41 such that in case the probes 441 need to be cleaned, such cleaning process can be directly performed in the chamber 41 without shutting down the test. In this way, not only the maintenance efficiency is improved, the possibility of malfunction or test failure due to dirt can also be reduced.

In another perspective of the present invention, referring to FIG. 4, a test carrier 42 used in a chamber 41 of a test handler 40 is provided. The test handler 40 can be used for IC chip tests in multiple temperature environments. The chamber 41 is controllable to present a dry status. The test carrier 42 for example can have a circular wafer shape similar to a semiconductor wafer and include plural positioning structures 422 to respectively accommodate the IC chips under test. The test carrier 42 controls the temperature of the IC chips by thermal conduction which transfers heat from/to the temperature-adjustment device 43. The IC chips can be inserted, pressed, plugged, or sucked into the positioning structures 422; preferably, the side of the IC chip having the contact pins faces upwards to facilitate the test process. The test carrier 42 is for example made of a metallic material.

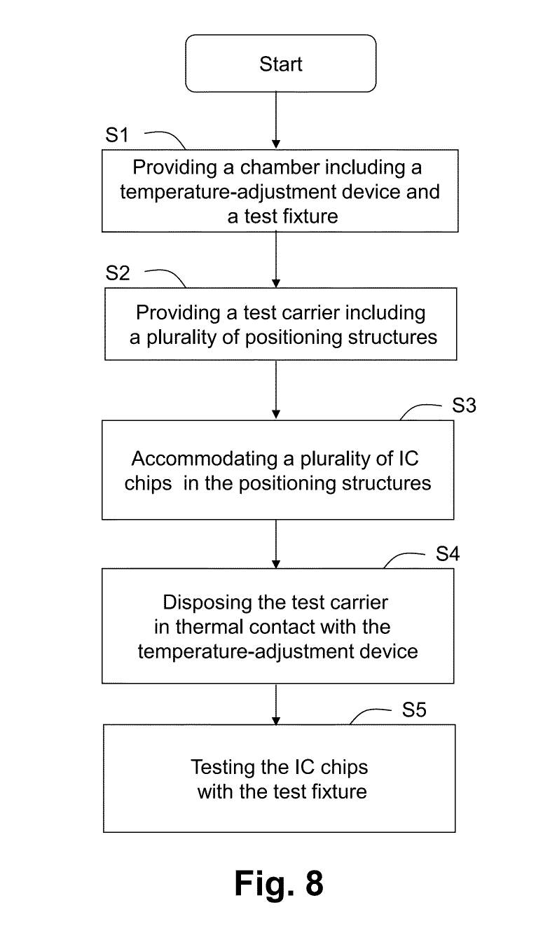

Referring to FIGS. 4, 5, and 8, according to another perspective of the present invention, a test method for IC chips is also provided. The test method can be used for IC chip tests in multiple temperature environments. The method includes: providing a humidity-controllable chamber 41 (S1), the chamber 41 including a temperature-adjustment device 43 and a test fixture 44; providing a test carrier 42 preferably having a high thermal conductivity, the test carrier 42 including plural positioning structures 422 (S2);

accommodating plural IC chips in the positioning structures 422 (S3); disposing the test carrier 42 on the temperature-adjustment device 43 and in thermal contact with the temperature-adjustment device 43 (S4), whereby the temperature of the IC chips is controlled by a thermal conduction of heat transferred from/to the temperature-adjustment device 43; and testing the IC chips by the test fixture 44 (S5).

In a preferable embodiment, referring to FIGS. 6A and 6B, the step of disposing the test carrier 42 on the temperature-adjustment device 43 and in thermal contact with the temperature-adjustment device 43 (S4) further includes: sensing a position of a probe 441 of the test fixture 44 and a position of a pin of the IC chip by an image sensor 45, to obtain a relative distance of the probes 441 and the IC chip pins; and ligning the probe 441 and the IC chip according to the obtained relative distance.

In comparison with the prior art test handlers, the present invention has the following advantages:

1. Flexibility to support tests of IC chips of different sizes, in particular a good solution for small size IC chips;

2. High throughput, because the number of IC chips under test per test (in one batch or one round of temperature adjustment) is much higher than the prior art test handlers;

3. Good expandability, because to increase the number of IC chips under test or to test IC chips of different sizes, it only needs to modify the design of the test carrier and the related cost is limited;

4. Low trouble shooting demand;

5. Less space occupied because it does not require a preheating/pre-cooling chamber; and

6. Suitable for non-temperature tests by high efficiency, because it can shorten the time required to switch between different environment temperatures.

The present invention has been described in considerable detail with reference to certain preferred embodiments thereof. It should be understood that the description is for illustrative purpose, not for limiting the scope of the present invention. The abstract and the title are provided for assisting searches and not to be read as limitations to the scope of the present invention. An embodiment or a claim of the present invention does not need to attain or include all the objectives, advantages or features described in the above. Those skilled in this art can readily conceive variations and modifications within the spirit of the present invention. For example, the alignment between the test fixture and the IC chips does not have to be achieved by image identification, or for another example, the chamber 41 does not have to be fully sealed. For example, the order of the step S1 and the step S2 is interchangeable, or for another example, the temperature-adjustment device does not have to include a pipe and it can be made by or include a high thermal conductive material. Further, although it is one benefit of the present invention that the present invention does not require a preheating/pre-cooling chamber, the present invention does not exclude the providing a preheating/pre-cooling chamber. These and other variations and modifications should fall within the scope of the present invention.

What is claimed is:

1. A test handler for an IC chip test, comprising:
a chamber;
a temperature-adjustment device in the chamber;
a test carrier in the chamber, including a plurality of positioning structures for respectively accommodating the IC chips, the test carrier being in thermal contact with the temperature-adjustment device, wherein the temperature-adjustment device controls the temperature of the IC chips on the test carrier by thermal conduction through the test carrier; and
a test fixture in the chamber, for testing the IC chips.

2. The test handler of claim 1, wherein the temperature-adjustment device is a supporter including a pipe connected to an external heating/cooling fluid source, and the test carrier is disposed on the temperature-adjustment device.

3. The test handler of claim 1, wherein the temperature-adjustment device is movable and while moving, the temperature-adjustment device moves the test carrier along with the temperature-adjustment device for aligning the test carrier with respect to the test fixture.

4. The test handler of claim 1, wherein the IC chips are inserted, pressed, plugged, or sucked into the positioning structures and a side of each IC chip which has contact pins face upwards.

5. The test handler of claim 1, wherein the test fixture includes at least one probe, and the test handler further includes a cleaning pad in the chamber for cleaning the probe.

6. The test handler of claim 1, further comprising an image sensor for sensing the position of the test fixture and/or the test carrier, and the test carrier and the test fixture are aligned with each other according to the information obtained by the image sensor.

7. The test handler of claim 1, wherein the test carrier is made of a high thermal-conductive material.

8. The test handler of claim 1, wherein the test carrier has a circular wafer shape.

9. The test handler of claim 1, wherein the chamber is controllable to present a dry status.

10. A test carrier, for use in a chamber of a test handler including a temperature-adjustment device, the test carrier comprising a plurality of positioning structures for respectively accommodating IC chips, and the test carrier being made of a high thermal-conductive material, whereby the test carrier controls the temperature of the IC chips by transferring heat from/to the temperature-adjustment device by thermal conduction when the test carrier is placed in contact with the temperature-adjustment device.

11. The test carrier of claim 10, which has a circular wafer shape.

12. The test carrier of claim 10, wherein the test carrier is made of a metallic material.

13. A test method for IC chips, comprising:
providing a chamber including a temperature-adjustment device and a test fixture;
providing a test carrier including a plurality of positioning structures;
respectively accommodating a plurality of IC chips in the positioning structures;
disposing the test carrier in thermal contact with the temperature-adjustment device; and
testing the IC chips by the test fixture.

14. The test method of claim 13, wherein by termal contact between the test carrier and the temperature-adjustment device, temperature of the IC chips is controlled by thermal conduction wherein heat is transferred from/to the temperature-adjustment device.

15. The test method of claim 13, wherein the chamber is controllable to present a dry status.

16. The test method of claim 13, wherein the test fixture includes at least one probe, and the test method further includes: providing a cleaning pad in the chamber for cleaning the probe.

17. The test method of claim 13, wherein he test fixture includes at least one probe, and the step of testing the IC chips with the test fixture includes:
sensing a position of the probe and a position of at least one IC chip by at least one image sensor, to obtain information of a relative distance between the probe and the IC chip; and
aligning the probe and the IC chips according to the relative distance information.
